(19) United States
(12) Patent Application Publication
(10) Pub. No.: US 2006/0055446 A1
(43) Pub. Date: Mar. 16, 2006

(54) Electronic circuits utilizing normally-on junction field-effect transistor

(76) Inventors: Liang-Pin Tai, Tainan (TW); Jing-Meng Liu, Hsinchu (TW); Hung-Der Su, Luju Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/220,556

(22) Filed: Sep. 8, 2005

(30) Foreign Application Priority Data
Sep. 10, 2004 (TW) 093127480

(51) Int. Cl. H03K 17/687

(52) U.S. Cl. 327/430

(57) ABSTRACT

Electronic circuits use low-cost depletion-mode JFET to serve as power switch. Since depletion-mode JFET has smaller conductive resistance and is majority carrier device, the energy loss is less when current flows through the depletion-mode JFET, and faster switching speed is obtained, thereby enhancing the efficiency of the electronic circuits.

### FIELD OF THE INVENTION

The present invention is related to electronic circuits utilizing normally-on junction field-effect transistor (JFET).

### BACKGROUND OF THE INVENTION

In current state-of-art electronic circuits, it is typically using bipolar junction transistor (BJT), metal-oxidant-semiconductor field-effect transistor (MOSFET) or silicon controlled rectifier (SCR) to serve as power switch. However, the switching loss when switching these elements is significantly great, thereby reducing the efficiency of the electronic circuits using them. Switching loss is related to the conductive resistance and switching speed of the elements. The greater the conductive resistance of a power switch is, the more the heat produced by current flowing therethrough is. The slower the switching speed of an element is, the greater the energy consumption of each switching is.

### SUMMARY OF THE INVENTION

Accordingly, the present invention is to provide an electronic circuit utilizing normally-on JFET for efficiency improvement.

According to the present invention, depletion-mode JFET is used in electronic circuits to serve as power switch. Since depletion-mode JFET has smaller conductive resistance than those of BJT, MOSFET and SCR, the heat generated by the current flowing through depletion-mode JFET is less. Further, depletion-mode JFET is majority carrier device, and therefore its switching speed is faster than those of BJT, MOSFET and SCR. As a result, in the electronic circuits, the switching loss is reduced, and the efficiency is enhanced.

### BRIEF DESCRIPTION OF DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows an asynchronous boost voltage converter according to the present invention;

FIG. 2 shows a synchronous boost voltage converter according to the present invention;

FIG. 3 shows an asynchronous buck voltage converter according to the present invention;

FIG. 4 shows a synchronous buck voltage converter according to the present invention;

FIG. 5 shows a synchronous inverting voltage converter according to the present invention;

FIG. 6 shows an asynchronous inverting voltage converter according to the present invention;

FIG. 7 shows a switching circuit according to the present invention; and

FIG. 8 shows a current sense circuit according to the present invention.

### DETAILED DESCRIPTION OF THE INVENTION

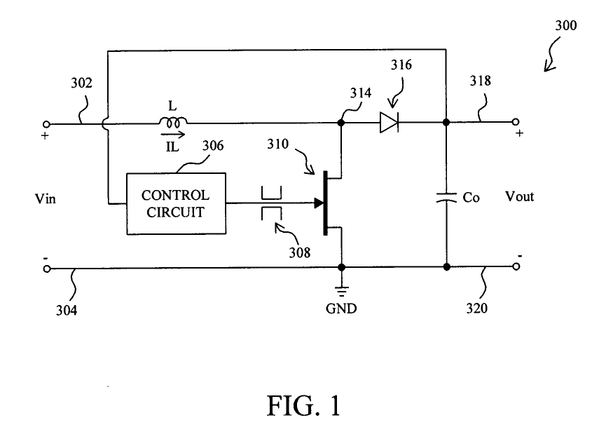

FIG. 1 shows an asynchronous boost voltage converter 300, which is a two-port circuit having positive input 302 coupled with input voltage Vin, negative input 304 coupled to ground GND, positive output 318 coupled to load, and negative output 320 coupled to ground GND. In the converter 300, inductor L is coupled between the positive input 302 and node 314, N-type depletion-mode JFET 310 is coupled between the node 314 and ground GND, control circuit 306 is used to switch the depletion-mode JFET 310, and current limiter 308 is coupled between the control circuit 306 and depletion-mode JFET 310. Changing the parameters of the control circuit 306 may change the switching frequency of the depletion-mode JFET 310. When the depletion-mode JFET 310 turns on, the inductor L is charged to store energy, until the depletion-mode JFET 310 is turned off by the control circuit 306, inductor current IL is produced from the energy stored in the inductor L to flow through rectifier diode 316 to charge capacitor Co to thereby obtain output voltage Vout on the output 318. The output voltage Vout and input voltage Vin have a ratio equal to that of the on-time of the depletion-mode JFET 310 to the sum of the on-time and off-time of the depletion-mode JFET 310. In some other embodiments, the N-type depletion-mode JFET 310 may be replaced by P-type depletion-mode JFET.

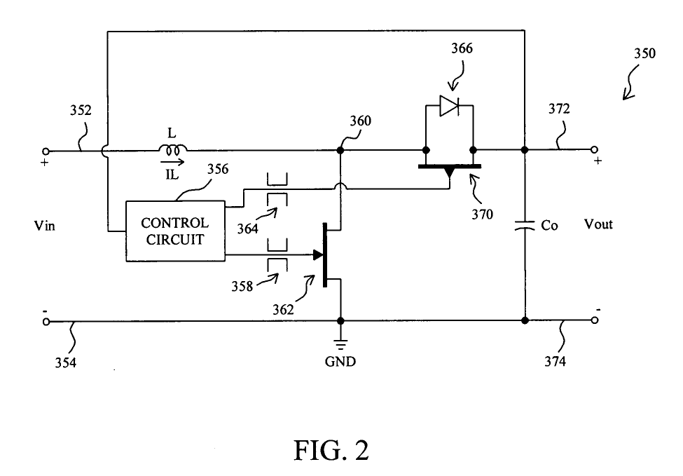

FIG. 2 shows a synchronous boost voltage converter 350, which is a two-port circuit having positive input 352 coupled with input voltage Vin, negative input 354 coupled to ground GND, positive output 372 coupled to load, and negative output 374 coupled to ground GND, N-type depletion-mode JFET 362 coupled between node 360 and ground GND for serving as switch, P-type depletion-mode JFET 370 coupled between the node 360 and positive output 372 for serving as switch, control circuit 356 for switching the depletion-mode JFETs 362 and 370, and current limiters 358 and 364 inserted between the control circuit 356 and the depletion-mode JFETs 362 and 370, respectively. Changing the parameters of the control circuit 356 may change the switching frequency of the depletion-mode JFETs 362 and 370. When the depletion-mode JFET 362 turns on, the depletion-mode JFET 370 is turned off, and inductor L is charged to store energy, until the depletion-mode JFET 362 turns off and the depletion-mode JFET 370 turns on, inductor current IL is produced from the energy stored in the inductor L to flow through the depletion-mode JFET 370 to charge capacitor Co to thereby obtain output voltage Vout on the positive output 372. The diode 366 coupled in parallel to the depletion-mode JFET 370 is for providing a current path when the depletion-mode JFETs 362 and 370 both turn off. In some other embodiments, the N-type depletion-mode JFET 362 may be replaced by P-type depletion-mode JFET, and the P-type depletion-mode JFET 370 may also be replaced by N-type depletion-mode JFET. Moreover, if the depletion-mode JFETs 362 and 370 are one N-type and one P-type, it may use only one current limiter for the control circuit 356 when switching the depletion-mode JFETs 362 and 370.

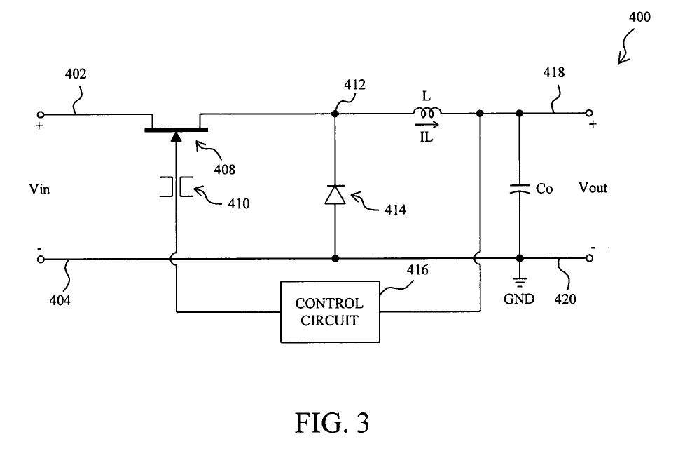

FIG. 3 shows an asynchronous buck voltage converter 400, which is also a tow-port circuit and has positive input 402 coupled with input voltage Vin, negative input 404 coupled to ground GND, positive output 418 coupled to load, and negative output 420 coupled to ground GND, N-type depletion-mode JFET 408 coupled between the positive input 402 and node 412, rectifier diode 414 coupled between the node 412 and ground GND, and current limiter 410 coupled between the gate of the depletion-mode JFET 408 and control circuit 416. The control circuit 416 senses the output voltage Vout on the positive output 418 to switch the depletion-mode JFET 408 accordingly. Changing the parameters of the control circuit 416 may change the switching frequency of the depletion-mode JFET 408. When the depletion-mode JFET 408 turns on, inductor L is charged to store energy, and capacitor Co is also under charged, until the depletion-mode JFET 408 turns off, inductor current IL is produced from the energy stored in the inductor L to charge the capacitor Co to thereby obtain the output voltage Vout. The output voltage Vout and input voltage Vin have a ratio equal to that of the on-time of the depletion-mode JFET 408 to the sum of the on-time and off-time of the depletion-mode JFET 408. In some other embodiments, the N-type depletion-mode JFET 408 may be replaced by P-type depletion-mode JFET.

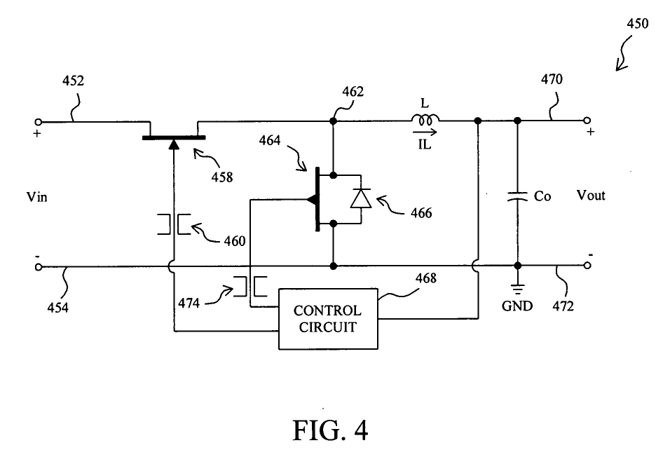

FIG. 4 shows a synchronous buck voltage converter 450, which is a two-port circuit having positive input 452 coupled with input voltage Vin, negative input 454 coupled to ground GND, positive output 470 coupled to load, and negative output 472 coupled to ground GND, N-type depletion-mode JFET 458 coupled between the positive input 452 and node 462, P-type depletion-mode JFET 464 coupled between the node 462 and ground GND, and control circuit 468 for sensing the output voltage Vout on the positive output 470 to produce signals through current limiters 460 and 474 to switch the depletion-mode JFETs 458 and 464. Changing the parameters of the control circuit 468 may change the switching frequency of the depletion-mode JFETs 458 and 464. When the depletion-mode JFET 458 turns on and the depletion-mode JFET 464 turns off, inductor L and capacitor Co are both charged, until the depletion-mode JFET 458 turns off and the depletion-mode JFET 464 turns on, inductor current IL is produced from the energy stored in the inductor L to charge the capacitor Co to thereby obtain the output voltage Vout. The diode 464 coupled in parallel to the depletion-mode JFET 464 is for providing current path when the depletion-mode JFETs 458 and 464 both turn off. In some other embodiments, the N-type depletion-mode JFET 458 may be replaced by P-type depletion-mode JFET, and the P-type depletion-mode JFET 466 may be replaced by N-type depletion-mode JFET. Moreover, if the depletion-mode JFETs 458 and 464 are one N-type and one P-type, it may use only one current limiter for the control circuit 468 when switching the depletion-mode JFETs 458 and 464.

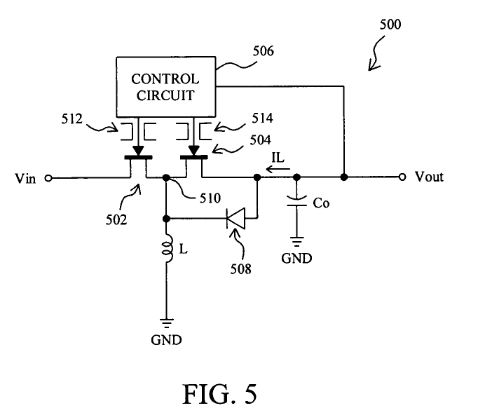

FIG. 5 shows a synchronous inverting voltage converter 500, in which the depletion-mode JFET 502 is coupled between input voltage Vin and node 510, another depletion-mode JFET 504 is coupled between the node 510 and output Vout, inductor L is coupled between the node 510 and ground GND, control circuit 506 is for switching the depletion-mode JFETs 502 and 504, and current limiters 512 and 514 are inserted between the control circuit 506 and the depletion-mode JFETs 502 and 504, respectively. When the depletion-mode JFET 502 turns on and the depletion-mode JFET 504 turns off, the inductor L is charged to store energy, until the depletion-mode JFET 502 turns off and the depletion-mode JFET 504 turns on, inductor current IL is produced from the energy stored in the inductor L to charge capacitor Co to thereby obtain output voltage Vout. Diode 508 is coupled between the node 510 and output Vout to maintain a current flowing therethrough when the depletion-mode JFETs 502 and 504 both turn off. In this embodiment, the depletion-mode JFETs 502 and 504 are both N-type, while in some other embodiments, they may be one N-type and one P-type, or both P-type.

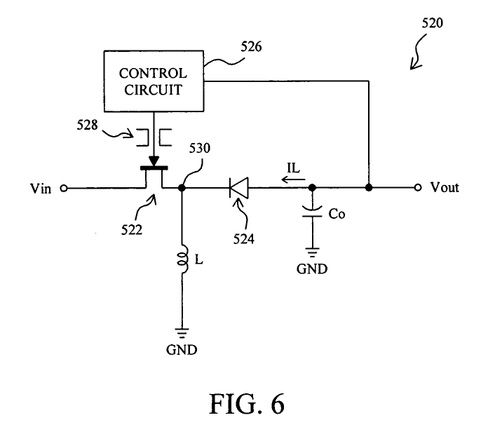

FIG. 6 shows an asynchronous inverting voltage converter 520, in which depletion-mode JFET 522 is coupled between input voltage Vin and node 530, rectifier diode 524 is coupled between the node 530 and output Vout, inductor L is coupled between the node 530 and ground GND, control circuit 526 is for switching the depletion-mode JFET 522, and current limiter 528 is inserted between the control circuit 526 and depletion-mode JFET 522. When the depletion-mode JFET 522 turns on, the inductor L is charged to store energy, until the depletion-mode JFET 522 turns off, inductor current IL is produced from the energy stored in the inductor L to charge capacitor Co to thereby obtain output voltage Vout. In this embodiment, the depletion-mode JFET 522 is N-type, while in some other embodiments, it may be P-type.

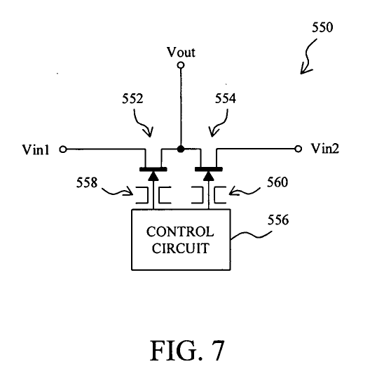

FIG. 7 shows a switching circuit 550, in which depletion-mode JFET 552 is coupled between input voltage Vin1 and output Vout, and depletion-mode JFET 554 is coupled between the output Vout and input voltage Vin2, control circuit 556 is for switching the depletion-mode JFETs 552 and 554, and current limiters 558 and 560 are inserted between the control circuit 556 and the depletion-mode JFETs 552 and 554, respectively. When the depletion-mode JFET 552 turns on and the depletion-mode JFET 554 turns off, the voltage on the output Vout is Vin1, while when the depletion-mode JFET 552 turns off and the depletion-mode JFET 554 turns on, the voltage on the output Vout is Vin2. In this embodiment, the depletion-mode JFETs 552 and 554 are both N-type, while in some other embodiments, they may be one N-type and one P-type, or both P-type.

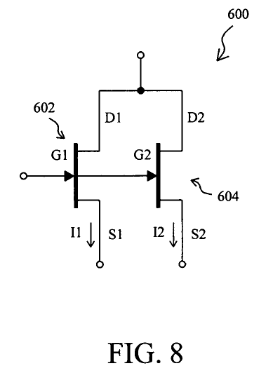

FIG. 8 shows a current sense circuit 600, in which depletion-mode JFET 602 has gate G1, drain D1 and source S1, and depletion-mode JFET 604 has gate G2 common to the gate G1, drain D2 common to the drain D1, and source S2. When current I1 flows through the depletion-mode JFET 602, the depletion-mode JFET 604 will conduct current I2 proportional to the current I1, and therefore the current I1 may be precisely sensed by sensing the current I2. In this embodiment, the depletion-mode JFETs 602 and 604 are both N-type, while in some other embodiments, they may be both P-type.

Since depletion-mode JFET has lower conductive resistance and is majority carrier device, the energy loss is less when current flows therethrough, and its switching speed is faster, thereby enhancing the performance of electronic circuits. Further, the above embodiments are designed in the form of several popular electronic circuits only for the purpose of illustrating the principles of the present invention, and other electronic circuits having power switch are also applicable to be implemented according to the present invention.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A boost voltage converter comprising:
a rectifier element coupled between a node and a capacitor;
an inductor coupled between an input voltage and the node;
a depletion-mode JFET coupled between the node and a reference; and
a control circuit for switching the depletion-mode JFET;
wherein an inductor current is produced from energy stored in the inductor by switching the depletion-mode JFET to charge the capacitor to produce an output voltage.

2. The converter of claim 1, wherein the control circuit determines a switching frequency of the depletion-mode JFET.

3. The converter of claim 1, wherein the output voltage and input voltage have a ratio equal to that of an on-time of the depletion-mode JFET to a sum of the on-time and an off-time of the depletion-mode JFET.

4. A boost voltage converter comprising:
a two-port circuit including a positive input, a negative input, a positive output and a negative output, the negative input and negative output coupled to a reference, the positive input coupled with an input voltage;
a rectifier element coupled between a node and the positive output;
a capacitor coupled between the positive output and negative output;
an inductor coupled between the positive input and node;
a depletion-mode JFET coupled between the node and reference; and
a control circuit for switching the depletion-mode JFET;
wherein an inductor current is produced from energy stored in the inductor by switching the depletion-mode JFET to charge the capacitor to produce an output voltage.

5. The converter of claim 4, wherein the control circuit determines a switching frequency of the depletion-mode JFET.

6. The converter of claim 4, wherein the output voltage and input voltage have a ratio equal to that of an on-time of the depletion-mode JFET to a sum of the on-time and an off-time of the depletion-mode JFET.

7. The converter of claim 4, further comprising a current limiter coupled between the control circuit and depletion-mode JFET.

8. A boost voltage converter comprising:
a two-port circuit including a positive input, a negative input, a positive output and a negative output, the negative input and negative output coupled to a reference, the positive input coupled with an input voltage;
a capacitor coupled between the positive output and negative output;
an inductor coupled between the positive input and a node;
a first JFET coupled between the node and reference;
a second JFET coupled between the node and positive output, and
a control circuit for switching the first and second JFETs;
wherein an inductor current is produced from energy stored in the inductor by switching the first and second JFETs to charge the capacitor to produce an output voltage.

9. The converter of claim 8, wherein the first JFET is either N-type or P-type JFET.

10. The converter of claim 8, wherein the second JFET is either N-type or P-type JFET.

11. The converter of claim 8, wherein the control circuit determines a switching frequency of the first and second JFETs.

12. The converter of claim 8, further comprising a current limiter coupled between the control circuit and the first and second JFETs.

13. The converter of claim 8, further comprising a first current limiter coupled between the control circuit and first JFET, and a second current limiter coupled between the control circuit and second JFET.

14. The converter of claim 8, further comprising a rectifier element coupled between the node and output for providing a current path when the first and second JFET both turn off.

15. A buck voltage converter comprising:
an inductor coupled between a node and a capacitor;
a depletion-mode JFET coupled between an input voltage and the node;
a rectifier element coupled between the node and a reference; and
a control circuit for switching the depletion-mode JFET;
wherein an inductor current is produced from energy stored in the inductor by switching the depletion-mode JFET to charge the capacitor to produce an output voltage.

16. The converter of claim 15, wherein the control circuit determines a switching frequency of the depletion-mode JFET.

17. The converter of claim 15, wherein the output voltage and input voltage have a ratio equal to that of an on-time of the depletion-mode JFET to a sum of the on-time and an off-time of the depletion-mode JFET.

18. A buck voltage converter comprising:
a two-port circuit including a positive input, a negative input, a positive output and a negative output, the negative input and negative output coupled to a reference, the positive input coupled with an input voltage;
a depletion-mode JFET coupled between the positive input and a node;
a capacitor coupled between the positive output and negative output;
an inductor coupled between the node and positive output;
a rectifier element coupled between the node and reference; and
a control circuit for switching the depletion-mode JFET;
wherein an inductor current is produced from energy stored in the inductor by switching the depletion-mode JFET to charge the capacitor to produce an output voltage.

19. The converter of claim 18, wherein the control circuit determines a switching frequency of the depletion-mode JFET.

20. The converter of claim 18, wherein the output voltage and input voltage have a ratio equal to that of an on-time of the depletion-mode JFET to a sum of the on-time and an off-time of the depletion-mode JFET.

21. The converter of claim 18, further comprising a current limiter coupled between the control circuit and depletion-mode JFET.

22. A buck voltage converter comprising:
a two-port circuit including a positive input, a negative input, a positive output and a negative output, the negative input and negative output coupled to a reference, the positive input coupled with an input voltage;
a capacitor coupled between the positive output and negative output;
a first JFET coupled between the positive input and a node;
a second JFET coupled between the node and reference;
an inductor coupled between the node and positive output; and
a control circuit for switching the first and second JFETs;
wherein an inductor current is produced from energy stored in the inductor by switching the first and second JFETs to charge the capacitor to produce an output voltage.

23. The converter of claim 22, wherein the first and second JFETs are one N-type and one P-type.

24. The converter of claim 22, wherein the control circuit determines a switching frequency of the first and second JFETs.

25. The converter of claim 22, further comprising a current limiter coupled between the control circuit and the first and second JFETs, respectively.

26. The converter of claim 22, further comprising a first current limiter coupled between the control circuit and first JFET, and a second current limiter coupled between the control circuit and second JFET.

27. The converter of claim 22, further comprising a rectifier element coupled between the node and reference for providing a current path when the first and second JFETs both turn off.

28. An inverting voltage converter comprising:
a first switch coupled between an input voltage and a node;
a second switch coupled between the node and an output;
an inductor coupled between the node and a reference;
a capacitor coupled between the output and reference; and
a control circuit for switching the first and second switches to produce an inductor current from energy stored in the inductor to charge the capacitor to produce an output voltage;
wherein at least one of the first and second switches is depletion-mode JFET.

29. The converter of claim 28, further comprising a first current limiter coupled between the first switch and control circuit, and a second current limiter coupled between the second switch and control circuit.

30. The converter of claim 28, wherein the first switch is either N-type or P-type depletion-mode JFET.

31. The converter of claim 28, wherein the second switch is either N-type or P-type depletion-mode JFET.

32. The converter of claim 28, further comprising a rectifier element coupled between the node and output for providing a current path when the first and second JFETs both turn off.

33. An inverting voltage converter comprising:
a depletion-mode JFET coupled between an input voltage and a node;
a rectifier element coupled between the node and an output;
an inductor coupled between the node and a reference;
a capacitor coupled between the output and reference; and
a control circuit for switching the depletion-mode JFET to produce an inductor current from energy stored in the inductor to charge the capacitor to produce an output voltage.

34. The converter of claim 33, further comprising a current limiter coupled between the depletion-mode JFET and control circuit.

35. The converter of claim 33, wherein the depletion-mode JFET is either N-type or P-type.

36. A switching circuit comprising:
a first switch coupled between a first voltage and an output;
a second switch coupled between the output and a second voltage; and
a control circuit for switching the first or second voltage to the output;
wherein at least one of the first and second switches is depletion-mode JFET.

37. The converter of claim 36, further comprising a first current limiter coupled between the first switch and control circuit, and a second current limiter coupled between the second switch and control circuit.

38. The converter of claim 36, wherein the first switch is either N-type or P-type depletion-mode JFET.

39. The converter of claim 36, wherein the second switch is either N-type or P-type depletion-mode JFET.

40. A current sense circuit comprising:
a first depletion-mode JFET having a first gate, a first drain and a first source; and
a second depletion-mode JFET having a second gate common to the first gate, a second drain common to the first drain, and a second source;
wherein the currents flow through the first and second depletion-mode JFETs are proportional to each other.

41. The circuit of claim 40, wherein the first and second depletion-mode JFETs are both N-type.

42. The circuit of claim 40, wherein the first and second depletion-mode JFETs are both P-type.
